(19) United States
(12) Patent Application Publication
(10) Pub. No.: US 2015/0271908 A1
(43) Pub. Date: Sep. 24, 2015

(54) COMPUTING DEVICE WITH PHASE CHANGE MATERIAL THERMAL MANAGEMENT

(71) Applicants: Manish Arora, Dublin, CA (US); Michael J. Schulte, Austin, TX (US)

(72) Inventors: Manish Arora, Dublin, CA (US); Michael J. Schulte, Austin, TX (US)

(21) Appl. No.: 14/218,801

(22) Filed: Mar. 18, 2014

(51) Int. Cl. H05K 1/02; H05K 13/00; H05K 7/20

(52) U.S. Cl. CPC H05K 1/0203; H05K 7/20336; H05K 13/00

(57) ABSTRACT

Apparatus including and methods of making and using container(s) of a phase change material are disclosed. In one aspect, an apparatus is provided that includes a computing device that has at least one heat generating component. A first container is external to and in thermal contact with the at least one heat generating component and has a first volume of a phase change material.

### BACKGROUND OF THE INVENTION

1. Field of the Invention

This invention relates generally to electronic devices, and more particularly to structures and methods for providing thermal management of electronic devices.

2. Description of the Related Art

Conventional schemes for thermally managing components of electronic devices normally entail placing some form of heat spreader in thermal contact with the component in question. A conventional heat spreader is typically constructed of some type of thermally conducting material and is often accompanied by some form of convective heat transfer. Some devices rely on natural convection. Others use forced convection through the usage of cooling fans. In some devices, liquid cooling schemes are used wherein a heat spreader is placed in contact with a component and a heat transfer fluid is mechanically pumped in a circuit that includes the heat spreader and some form of chiller. The chiller may simply involve a cooling fan and plurality of heat fins that are located remotely from the thermally managed component, but more complex systems may utilize refrigeration units.

Common to these conventional schemes is the treatment of the dissipated heat as a waste product. Furthermore, convective heat transfer systems quite often must pass the heated air across other components which may increase the temperatures of those components. While ducting can eliminate some of the problems of heated air increasing the temperature of surrounding components, such ducting can still exhibit air leakage. In addition, conventional water and air systems rely on the specific heats of those fluids and are thus limited by the physics of specific heat.

The present invention is directed to overcoming or reducing the effects of one or more of the foregoing disadvantages.

### SUMMARY OF THE INVENTION

In accordance with one aspect of the present invention, an apparatus is provided that includes a computing device that has at least one heat generating component. A first container is external to and in thermal contact with the at least one heat generating component and has a first volume of a phase change material.

In accordance with another aspect of the present invention, a method of thermally managing at least one heat generating component of a computing device is provided. The method includes placing a first container that has a first volume of a phase change material in thermal contact with the at least one heat generating component. The first container is external to the at least one heat generating component.

In accordance with another aspect of the present invention, a method of manufacturing is provided that includes placing a first volume of a phase change material in a first container. The first container is adapted to be external to at least one heat generating component of a computing device. The first container has at least one member adapted to establish thermal contact with the at least one heat generating component.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a computing device;

FIG. 2 is a plan view of an alternate exemplary computing device;

FIG. 3 is a plan view of another alternate exemplary computing device;

FIG. 4 is a plan view of another alternate exemplary computing device; and

FIG. 5 is a flow chart depicting an exemplary control loop using a PCM container for thermal management.

### DETAILED DESCRIPTION OF SPECIFIC EMBODIMENTS

One or more containers of a phase change material (PCM) are used to store heat generated by a heat generating component(s) of a computing device. The containers may be swapped with other containers of PCM as necessary. The stored heat may be used to generate electrical power that may be fed back to the computing device, some other device or sent to a storage device, such as a capacitive network. Additional details will now be described.

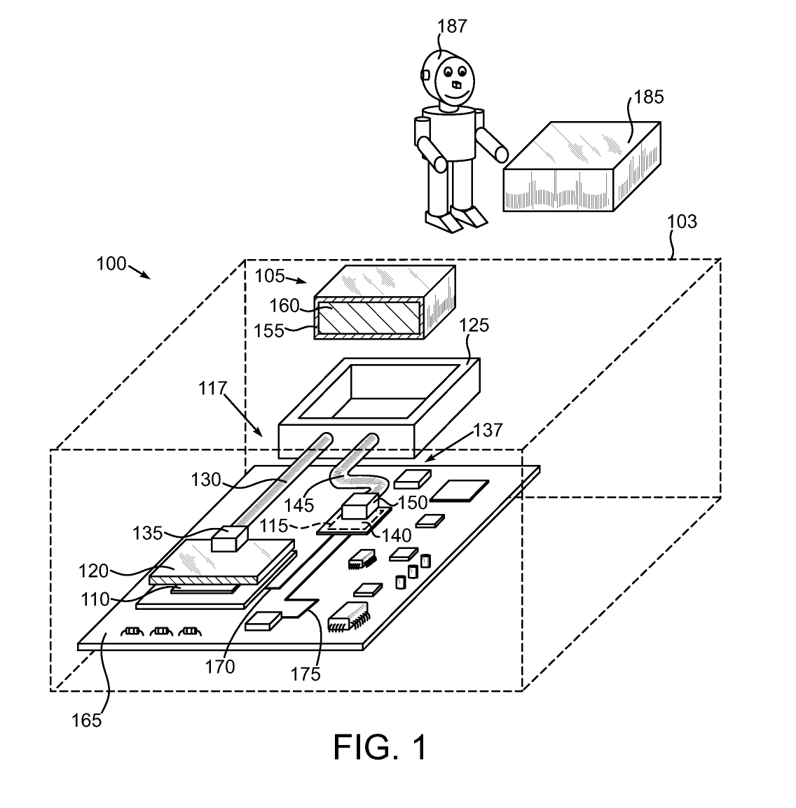

In the drawings described below, reference numerals are generally repeated where identical elements appear in more than one figure. Turning now to the drawings, and in particular to FIG. 1, therein is shown a pictorial view of an exemplary embodiment of a computing device 100 that may include an enclosure 103 (depicted schematically as a dashed box). The computing device 100 utilizes a phase change material container 105 to provide thermal management for one or more heat generating components 110 and 115 of the computing device 100. Note that the heat generating component 115 is obscured by a structure to be described below and is thus shown in phantom in FIG. 1. The PCM container 105 may be housed with the enclosure 103 or be externally positioned as described elsewhere herein.

The usage of a PCM container 105 to provide thermal management is not dependent on the functionalities of the computing device 100 or the heat generating components 110 and 115. Thus, the computing device 100 may be a computer, a digital television, a handheld mobile device, a personal computer, a server or virtually any type of electronic device that may benefit from thermal management. The heat generating components 110 and 115 may be microprocessors, graphics processors, combined microprocessor/graphics processors sometimes known as application processing units, application specific integrated circuits, memory devices, systems on a chip, optical devices, passive components, interposers, or other devices.

Thermal contact between the heat generating component 110 and the PCM container 105 may be provided by a member 117 coupled between those features 110 and 105. The member 117 may take on a variety of configurations. In an exemplary embodiment, the member 117 may include a heat spreader plate 120 seated on the component 110. The spreader plate 120 may be thermally connected to a frame or cradle 125 by way of one or more heat pipes, and in this case one heat pipe 130. The heat pipe 130 may be directly connected to the spreader plate 120 or by way of the disclosed coupling block 135. The heat generating component 115 may be similarly thermally connected to the frame 125 by way of a member 137, which includes a spreader plate 140 and a heat pipe 145 and an optional coupling block 150. The spreader plates 120 and 140, the connector blocks 135 and 150, as well as the heat pipes 130 and 145 may be constructed of well-known thermally conducting materials, such as copper, aluminum, nickel, stainless steel, brass, laminates of these or others. Somewhat more exotic materials, such as diamond or sapphire may be used for the spreader plates 120 and 140 where extreme temperatures are anticipated. The frame 125 is designed to removably receive the PCM container 105. Here the PCM container 105 is shown in section to reveal that the container 105 includes an outer shell 155 that holds a volume of a PCM 160. The frame 125 and shell 155 are advantageously constructed of a thermally conducting material such as those just described. Connections between items, such as the spreader plates 120 and 140, the heat pipes 130 and 145, the frame 125 and the blocks 135 and 150 may be by way of soldering, brazing, friction fits, mechanical fasteners or other techniques. Optionally, the members 117 and 137 may be constructed as unitary components, stamped, punched, machined, caste or otherwise constructed.

The computing device 100 may include a circuit board 165 (or multiple boards) upon which the heat generating components 110 and 115 may be mounted. The circuit board 165 may be populated with a variety of other components, which are not numerically labeled for simplicity of illustration, but which may include passive components, integrated circuits or virtually any other type of components used in electronics. The circuit board 165 may also include large numbers of conductor lines or traces, a couple of which are illustrated and labeled 170 and 175, respectively. The circuit board 165 may be a package substrate, a circuit card, a system board or virtually any other type of printed circuit board. The enclosure 103 may be composed of well-known plastics, metals or others, and take on a variety of shapes and sizes.

As heat is generated by the heat generating components 110 and 115, that heat is conveyed by way of the spreader plates 120 and 140 and the heat pipes 130 and 145 to the frame 125 and ultimately to the PCM 160. The PCM 160 will readily absorb and store heat while undergoing a change of physical phase, say from solid to liquid or from one solid phase to another. The heat can be released later during periods of reduced power consumption by the heat generating components 110 and 115. The PCM 160 and any alternatives thereof may be so-called solid-to-liquid phase materials or solid phase-to-solid phase materials. A large variety of different types of PCMs may be used. In general, there are three varieties of PCMs: (1) organic; (2) inorganic; and (3) eutectic. These categories may be further subdivided as follows:

TABLE 1
PCM MATERIAL CLASSIFICATION

| ORGANIC | INORGANIC | EUTECTIC |
|---|---|---|
| Paraffin | Salt Hydrate | Organic-Organic |
| Non-Paraffin | Metallic | Inorganic-Inorganic |

Inorganic-Organic

A variety of characteristics are desirable for the material(s) selected for the PCM 160 and any alternatives. A non-exhaustive list of the types of desired PCM characteristics includes a melting temperature Tₘ less than but close to the maximum anticipated chip operating temperature Tₘₐₓ, a high latent heat of fusion, a high specific heat, a high thermal conductivity, small volume change and congruent melting (for solid-to-liquid), high nucleation rate to avoid supercooling, chemical stability, low or non-corrosive, low or no toxicity, nonflammability, nonexplosive and low cost/high availability. Some of these characteristics may be favored over others for a given PCM. Table 2 below illustrates some exemplary materials for the PCM 160 and any alternatives.

TABLE 2

| | | Latent Heat | |
|---|---|---|---|
| | Melting Point | of Fusion | |
| Material | Tₘ (° C.) | (kJ/kg) | Notes |
| Paraffin | | | The numbers in |
| 21 | 40.2 | 200 | the first column |
| 22 | 44.0 | 249 | represent the |
| 23 | 47.5 | 232 | number of carbon |
| 24 | 50.6 | 255 | atoms for a given |
| 25 | 49.4 | 238 | form of paraffin |
| 26 | 56.3 | 256 | |
| 27 | 58.8 | 236 | |
| 28 | 61.6 | 253 | |
| 29 | 63.4 | 240 | |
| 30 | 65.4 | 251 | |
| 31 | 68.0 | 242 | |
| 32 | 69.5 | 170 | |
| 33 | 73.9 | 268 | |
| 34 | 75.9 | 269 | |
| Hydrocinnamic acid | 48.0 | 118 | |
| Cetyl alcohol | 49.3 | 141 | |
| α-Nepthylamine | 50.0 | 93 | |
| Camphene | 50 | 238 | |
| O-Nitroaniline | 50.0 | 93 | |
| 9-Heptadecanone | 51 | 213 | |
| Thymol | 51.5 | 115 | |
| Methyl behenate | 52 | 234 | |
| Diphenyl amine | 52.9 | 107 | |
| p-Dichlorobenzene | 53.1 | 121 | |
| Oxalate | 54.3 | 178 | |
| Hypophosphoric acid | 55 | 21 | |
| O-Xylene dichloride | 55.0 | 121 | |
| β-Chloroacetic acid | 56.0 | 147 | |
| Chloroacetic acid | 56 | 130 | |
| Nitro naphthalene | 56.7 | 103 | |
| Trimyristin | 33-57 | 201-213 | |
| Heptaudecanoic acid | 60.6 | 189 | |
| α-Chloroacetic acid | 61.2 | 130 | |
| Bees wax | 61.8 | 177 | |
| Glyolic acid | 63.0 | 109 | |
| p-Bromophenol | 63.5 | 86 | |
| Azobenzene | 67.1 | 121 | |
| Acrylic acid | 68.0 | 115 | |
| Dinto toluent (2,4) | 70.0 | 111 | |
| Na₂PO₄•12H₂0 | 40.0 | 279 | |
| CoSO₄•7H₂O | 40.7 | 170 | |
| KF•2H₂O | 42 | 162 | |
| MgI₂•8H₂O | 42 | 133 | |
| CaI₂•6H₂O | 42 | 162 | |
| K₂HPO₄•7H₂O | 45.0 | 145 | |
| Zn(NO₃)₂•4H₂O | 45 | 110 | |
| Mg(NO₃)•4H₂O | 47.0 | 142 | |
| Ca(NO₃)•4H₂O | 47.0 | 153 | |
| Fe(NO₃)₃•9H₂O | 47 | 155 | |
| Na₂SiO₃•4H₂O | 48 | 168 | |
| K₂HPO₄•3H₂O | 48 | 99 | |
| Na₂S₂O₃•5H₂O | 48.5 | 210 | |
| MgSO₄•7H₂O | 48.5 | 202 | |
| Ca(NO₃)₂•3H₂O | 51 | 104 | |
| Zn(NO₃)₂•2H₂O | 55 | 68 | |
| FeCl₃•2H₂O | 56 | 90 | |
| Ni(NO₃)₂•6H₂O | 57.0 | 169 | |
| MnCl₂•4H₂O | 58.0 | 151 | |
| MgCl₂•4H₂O | 58.0 | 178 | |
| CH₃COONa•3H₂O | 58.0 | 265 | |
| Fe(NO₃)₂•6H₂O | 60.5 | 126 | |
| NaAl(SO₄)₂•10H₂O | 61.0 | 181 | |
| NaOH•H₂O | 64.3 | 273 | |
| Na₃PO₄•12H₂O | 65.0 | 190 | |
| LiCH₃COO•2H₂O | 70 | 150 | |
| Al(NO₃)₂•9H₂O | 72 | 155 | |
| Ba(OH)₂•8H₂O | 78 | 265 | |
| Eladic acid | 47 | 218 | |
| Lauric acid | 49 | 178 | |
| Pentadecanoic acid | 52.5 | 178 | |
| Tristearin | 56 | 191 | |
| Myristic acid | 58 | 199 | |
| Palmatic acid | 55 | 163 | |
| Stearic acid | 69.4 | 199 | |
| Gallium-gallium | 29.8 | — | The dashes |
| antimony eutectic | | | indicate the value |
| | | | is unknown to the |
| | | | inventors at this |
| | | | time |
| Gallium | 30.0 | 80.3 | |
| Cerrolow eutectic | 58 | 90.9 | |
| Bi—Cd—In eutectic | 61 | 25 | |
| Cerrobend eutectic | 70 | 32.6 | |
| Bi—Pb—In eutectic | 70 | 29 | |
| Bi—In eutectic | 72 | 25 | |
| Bi—Pb-tin eutectic | 96 | — | The dashes |
| | | | indicate the value |
| | | | is unknown to the |
| | | | inventors at this |
| | | | time |
| Bi—Pb eutectic | 125 | — | The dashes |
| | | | indicate the value |
| | | | is unknown to the |
| | | | inventors at this |
| | | | time |

It should be understood that the PCM container 105 may be swapped out upon reaching its thermal limit and another PCM container 185 may be swapped in and placed in the frame 125. The changing of PCM containers 105 and 185 may be performed by robotic machines 187 or by hand. The skilled artisan will appreciate that the PCM containers 105 and 185 as well as the frame 125 may take on a large variety of different structural configurations. Examples include flat plates, cylindrical shells, cylinders or virtually any other shape. The material point is that the containers 105 and 185 are able to hold a quantity of the PCM 160 and establish satisfactory thermal contact with whatever heat conveyance apparatus are used, such as the heat pipes 130 and 145, etc.

A variety of techniques may be used to establish whether or not the thermal capacity of a given PCM container, such as the container 105, has been exhausted. For example, the thermal capacity h₁₀₅ of a given PCM container 105 in a computing device 100 may be modeled using a function:

h₁₀₅=g(Hₜₒₜₐₗ,P_{measured},Q,γ,t) (1)

where hₜₒₜₐₗ is the total heat absorption capacity of the PCM 160 in the container, P_{measured} is the measured power of the heat generating components 110 and 115, Q is conductive heat transfer rate of the thermal pathway, γ is a measure of the material characteristics of the PCM 160 and t is time. Depending on the capabilities of the computing device 100, the quantity P_{measured} can be determined with onboard circuitry and sensors or by way of external measurements. The quantity Q will be typically be given by:

Q=KΔT (2)

where K is the thermal conductivity K of the thermal pathway between the computing devices 110 and 115 and the PCM 160 and ΔT is the temperature difference between the those devices 110 and 115 and the PCM 160. The quantity γ may be based on, for example, the data in Table 2 above. The solution(s) to the Equation (1) may be determined using well-known numerical methods.

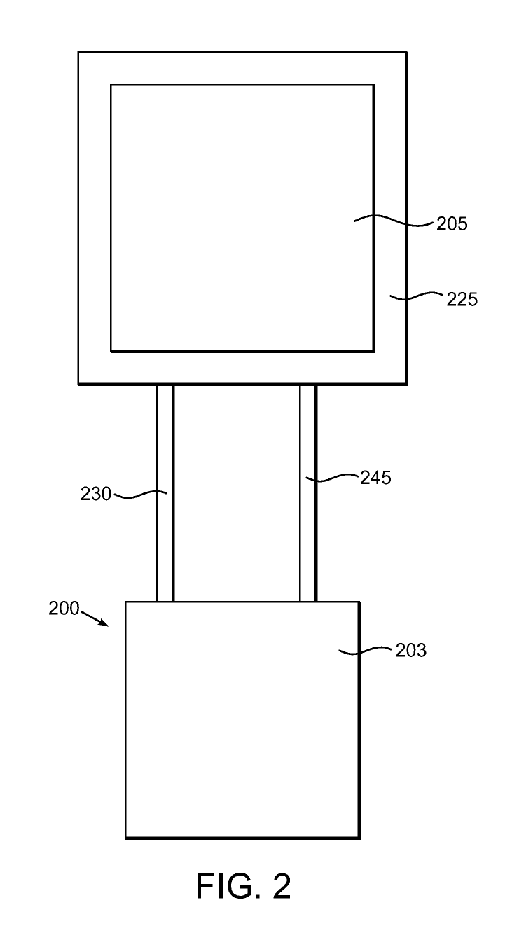

In the foregoing illustrative embodiment, the PCM containers 105 and 185 are positioned within a computing device enclosure 103. However, the skilled artisan will appreciate that it may be possible and indeed advantageous to position a PCM reservoir outside of the computing device enclosure. In this regard, attention is now turned to FIG. 2, which is a plan view of an exemplary computing device 200 that includes a suitable container or enclosure 203. Here, a PCM container 205 may be located external to the computing device enclosure 203 and thermally connected thereto by way of, for example, heat pipes 230 and 245 and the frame 225. The frame 225 may be slightly or even considerably larger than the computing device enclosure 203. Enlarged PCM containers may be suitable in circumstances where the heat generation of the computing device 200 is of such magnitude that a much proportionately larger PCM container 205 is necessary in order to effectively store the heat. Again, the number and types of thermal conveyance devices may be greatly varied and use devices other than the heat pipes 230 and 245 and certainly more then two or as desired. As with the FIG. 1 embodiment, the PCM container 205 may be swapped out for another (not shown) whenever it is determined that the PCM container 205 has reached it particular thermal limit.

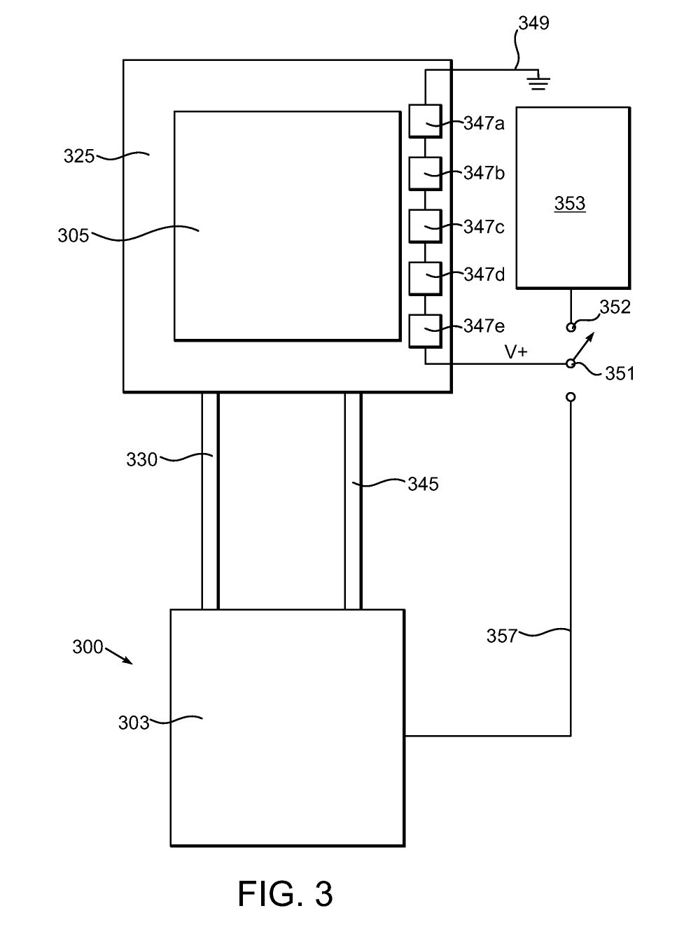

An alternate exemplary embodiment of a computing device 300 may be understood by referring now to FIG. 3, which is a plan/schematic view like FIG. 2. Here, the computing device 300 similarly includes an enclosure 303 and is thermally connected to a PCM container 305 that may be removably mounted to a frame 325. Similarly, thermal contact between the computing device 300 and the frame 325 may be provided by one or more heat pipes 330 and 345. In this illustrative embodiment, the waste heat is utilized to generate electrical power. This may be accomplished in a variety of ways. In this illustrative embodiment, the frame 325 may be provided with plural thermoelectric coolers 347a, 347b, 347c, 347d and 347e that may be connected in series to ground 349 as shown and also to a switch 351. The thermoelectric coolers 347a, 347b, 347c, 347d and 347e function to generate a voltage V+ in response to delivery of heat to the frame 325. The switch 351 is operable to selectively deliver the voltage V+ to an input 352 of an electronic device 353 or back to the computing device 300 via the input 357 where it may be used to power one or more components thereof. The electronic device 353 may be another computing device of the type describe elsewhere herein, a battery storage device, a cooling fan(s) or other electrical device. The switch 351 may be a variety of different types of multi-port switches, and may be solid state or electro-mechanical as desired.

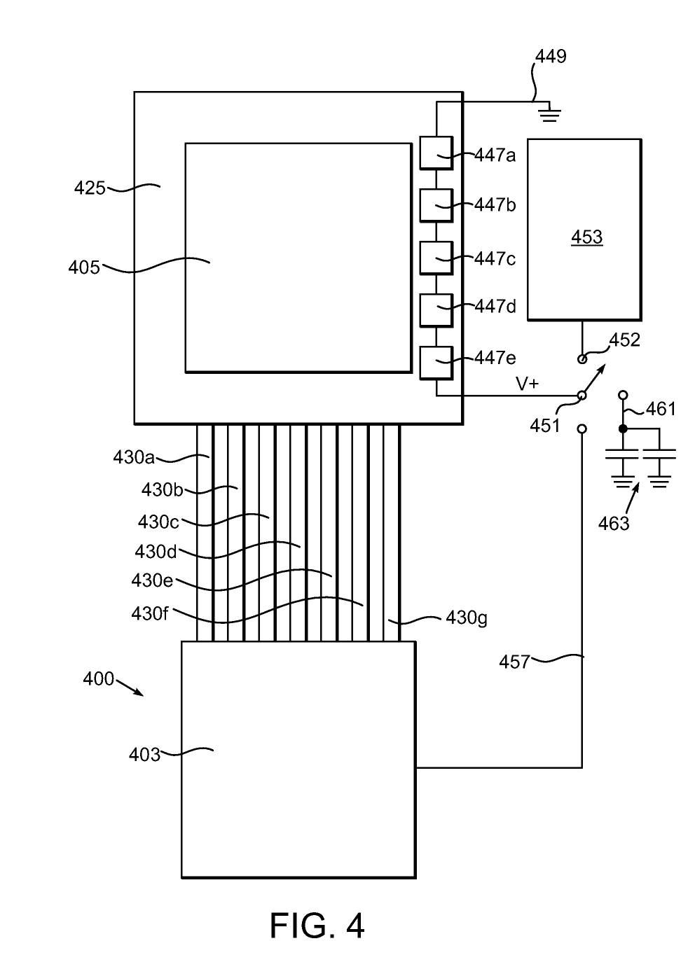

In still another alternate exemplary embodiment of a computing device 400, shown in FIG. 4, some type of enclosure 403 may be used as described above, as well as a PCM container 405 and a frame 425. Here, greater than two heat pipes may be used, and are labeled 430a, 430b, 430c, 430d, 430e, 430f and 430g, to establish thermal contact between the computing device 400 and the frame 425. The PCM container 405 may be swappable as described above in conjunction with the other embodiments. Similarly, the frame 425 may be provided with plural thermal electric coolers 447a, 447b, 447c, 447d and 447e that are series connected to ground 449 and some type of switch 451 that may selectively connect to an input 452 of an electronic device 453 or a return or other input 457 to the computing device 400 and thus serve to direct power back to the device 400. The electronic device 453 may be like the electronic device 353 just described. In this illustrative embodiment, an additional option for an output of the switch 451 is as an input 461 to a capacitive network schematically represented and numbered 463. The capacitive network 463 may consist of one or more capacitors preferably, but not necessarily connected in parallel, and arranged to be able to store power generated by the thermoelectric coolers 447a, 447b, 447c, 447d and 447e.

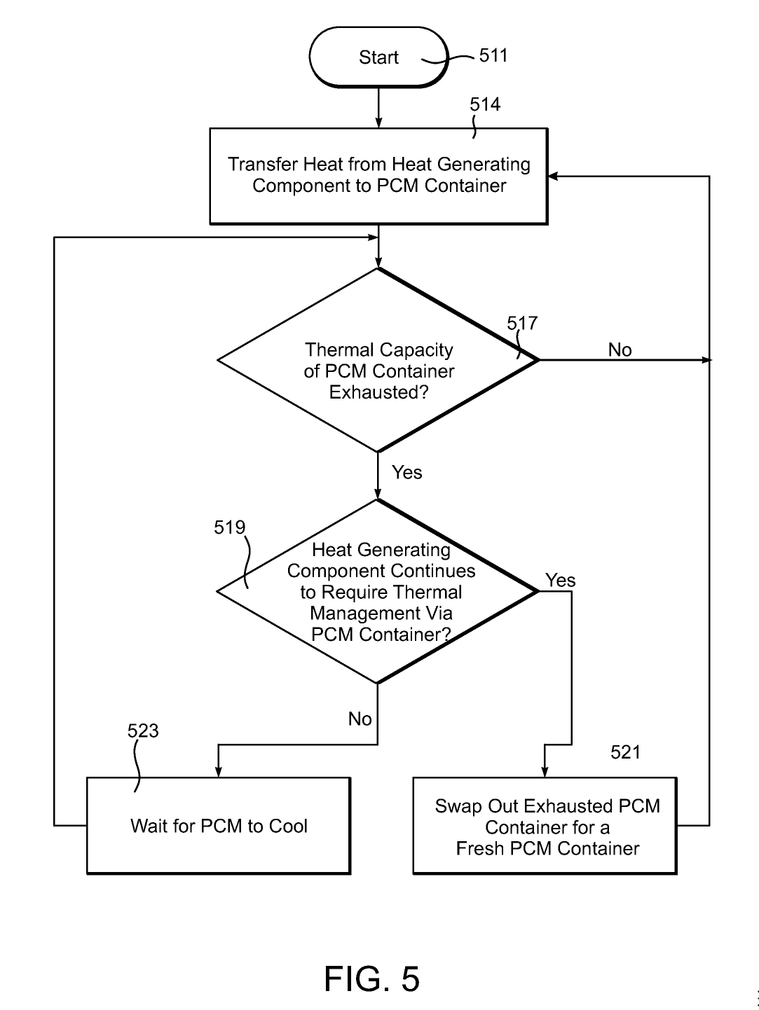

An exemplary control loop utilizing any of the disclosed embodiments of a computing device and a PCM container may be understood by referring now to FIG. 5, which is a flowchart. The loop starts at step 511. At step 514 heat is transferred from a heat generating component to a PCM container. At step 517, a determination is made as to whether or not the thermal capacity of the PCM container has been exhausted. This may entail application of the model of thermal capacity discussed above in conjunction with Equation (1). If not, then the loop returns to step 514 and heat transfer continues. If on the other hand, the thermal capacity of the PCM container has been exhausted at step 517, then at step 519 a determination is made as to whether or not the heat generating component continues to require thermal management via the PCM container. If yes, then at step 521, the expended PCM container may be swapped out for a fresh PCM container. If on the other hand, the heat generating component does not continue to require thermal management via the PCM container at step 519, then at step 523 the loop will wait for the PCM container to cool, and the progress of this cooling will be monitored by way of a return to step 517. The foregoing control loop represents just one of many possible types of control schemes that may be utilized in conjunction with a PCM container that is used to store heat from a computing device.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. An apparatus, comprising:
a computing device having at least one heat generating component; and
a first container having a first volume of a phase change material, the first container being external to and in thermal contact with the at least one heat generating component.

2. The apparatus of claim 1, wherein the computing device comprises an enclosure, the first container being inside or outside the enclosure.

3. The apparatus of claim 1, wherein the first container is swappable with a second container having a second volume of a phase change material.

4. The apparatus of claim 1, comprising at least one heat pipe providing thermal contact between the at least one heat generating component and the first container.

5. The apparatus of claim 1, wherein the at least heat generating component comprises a semiconductor chip.

6. The apparatus of claim 1, wherein the computing device comprises a circuit board, the at least one heat generating component being mounted on the circuit board.

7. The apparatus of claim 1, comprising a device coupled to the first container and being operable to generate electrical power in response to application of heat from the first volume of the phase change material.

8. The apparatus of claim 7, wherein the device is operable to deliver the electrical power back to the computing device.

9. The apparatus of claim 7, comprising a capacitive network, the device being operable to deliver the electrical power to the capacitive network for storage.

10. A method of thermally managing at least one heat generating component of a computing device, comprising:
placing a first container having a first volume of a phase change material in thermal contact with the at least one heat generating component, the first container being external to the at least one heat generating component.

11. The method of claim 10, wherein the computing device comprises an enclosure, the method comprising placing the first container inside or outside the enclosure.

12. The method of claim 10, comprising swapping the first container with a second container having a second volume of a phase change material.

13. The method of claim 12, comprising determining if the thermal capacity of the first volume of the phase change material is exhausted, and swapping the first and second containers if the first volume of the phase change material is exhausted.

14. The method of claim 10, comprising using at least one heat pipe to provide thermal contact between the at least one heat generating component and the first container.

15. The method of claim 10, wherein the at least heat generating component comprises a semiconductor chip.

16. The method of claim 10, comprising coupling a device to the first container, the device being operable to generate electrical power in response to application of heat from the first volume of the phase change material.

17. The method of claim 16, wherein the device is operable to deliver the electrical power back to the computing device.

18. The method of claim 16, wherein the device being operable to deliver the electrical power to a capacitive network for storage.

19. A method of manufacturing, comprising:
placing a first volume of a phase change material in a first container, the first container being adapted to be external to at least one heat generating component of a computing device and having at least one member adapted to establish thermal contact with the at least one heat generating component.

20. The method of claim 19, comprising removably coupling the first container to a frame.

21. The method of claim 19, wherein the computing device comprises an enclosure, the method comprising placing the first container inside or outside the enclosure.
